(19) United States
(12) Patent Application Publication
(10) Pub. No.: US 2008/0113283 A1
(43) Pub. Date: May 15, 2008

(54) SILOXANE EPOXY POLYMERS FOR REDISTRIBUTION LAYER APPLICATIONS

(75) Inventors: Ramkrishna Ghoshal, Clifton Park, NY (US); Pei-I Wang, Troy, NY (US); Toh-Ming Lu, Loudonville, NY (US); Rajat Ghoshal, Malta, NY (US); Ou Ya, Troy, NY (US)

Correspondence Address: HESLIN ROTHENBERG FARLEY & MESITI PC, 5 COLUMBIA CIRCLE, ALBANY, NY, 12203, US

(73) Assignees: POLYSET COMPANY, INC., Mechanicville, NY (US); RENSSELAER POLYTECHNIC INSTITUTE, Troy, NY (US)

(21) Appl. No.: 11/742,192

(22) Filed: Apr. 30, 2007

Related U.S. Application Data
(60) Provisional application No. 60/745,935, filed on Apr. 28, 2006.

(51) Int. Cl. G03F 9/00; B05D 3/06

(52) U.S. Cl. 430/22; 427/532; 427/386; 427/387

(57) ABSTRACT

Siloxane epoxy materials employed as redistribution layers in electronic packaging and coatings for imprinting lithography, and methods of fabrication are disclosed.

### CROSS-REFERENCE TO RELATED APPLICATIONS

This application claims priority from U.S. Provisional Application Ser. No. 60/745,935, filed on Apr. 28, 2006, the entire contents of which are incorporated herein by reference.

### FIELD OF THE INVENTION

The invention relates to siloxane epoxy materials employed as redistribution layers in electronic packaging and coatings for imprinting lithography, and methods of fabrication thereof.

### BACKGROUND OF THE INVENTION

The demand for higher density and faster chips is continuously growing for the semiconductor industry, leading to a pressing need for new materials and a new packaging approach for interconnects because interconnect technology, both on-chip and in packaging, has become a major limitation. The industry is developing new approaches such as flip chips and optical interconnects to overcome board-level limitations, but new materials are needed to facilitate these conversions.

Redistribution process is the first step of wafer-level packaging, which is an approach to flip chip technology that is being widely adopted by industry. In this approach, a photo-curable polymer film is deposited on the wafer. Multiple photolithography and metallization steps for redistributing the I/O pattern then follow. Redistribution process offers chip protection in the environmental and mechanical aspects based on the polymeric dielectric used in its fabrication. The redistribution layers generally require low water absorption, thermal stability to sustain the solder reflow, low curing temperature, low coefficient of thermal expansion (CTE), and electrical characteristics of low dielectric constant and low leakage current. Benzocyclobutene (BCB) or polyimide (PI) typically is used as the material for redistribution layers. BCB has been widely used for this application.

Another application is to create redistribution layers on a substrate to increase the number of pads that can be bumped for the flip chip technology. Again photolithography techniques have been used for this purpose. An alternative strategy is to use the newly developed microimprinting lithography (MIL) and nanoimprinting lithography techniques to create the patterns. Nanoimprint lithography is fully described by M. D. Stewart and C. G. Wilson in “Imprint Materials for Nanoscale Devices”, MRS Bulletin 30, 957-951 (2005), the entire contents of which are incorporated herein by reference.

The common issue for imprint and contact lithography is sticking between a resist and a template surface or a photomask surface due to the high surface energy of the materials used for the foregoing. A layer that could be coated on the template surface would be beneficial. The layer would be required to have a low surface energy to enable separation at the template (or photomask)/substrate interface. In addition, the bonding of the layer to the template surface would have to be robust enough to remain functional after many imprints.

A need exists for materials employed as redistribution layers in electronic packaging as well as materials employed for imprint and contact lithography that overcome at least one of the aforementioned deficiencies.

### SUMMARY OF THE INVENTION

An aspect of the present invention relates to a process for forming a redistribution layer in an electronic component comprising: providing a substrate; depositing a siloxane epoxy prepolymer film onto said substrate; laying an imprint template having a pattern thereon onto said prepolymer film to form an imprint template/prepolymer stack, said pattern having at least one dimension measuring between 1.0 nm and 10 μm; exposing said imprint template/siloxane epoxy prepolymer film stack to radiation; and removing said patterned imprint template to form a redistribution layer having an inverse pattern of said patterned soft mold.

A second aspect of the present invention relates to a process for forming a redistribution layer in an electronic component comprising: providing a substrate; depositing a siloxane epoxy prepolymer film comprising:

1) a compound of formula II:

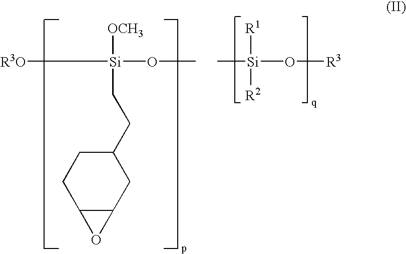

wherein

### R¹ and R² are independently selected from the group consisting of methyl, methoxy, ethyl, ethoxy, propyl, butyl, pentyl, octyl, phenyl, and fluoroalkyl;

### R³ is methyl or ethyl;

p is an integer from 2 to 50; and
q is 0 or an integer from 1 to 50;

2) a cationic polymerization initiator; and

3) optionally a photosensitizer, onto said substrate;

patternwise exposing said siloxane epoxy prepolymer film to actinic radiation; and developing said exposed siloxane epoxy prepolymer film so as to form a patterned redistribution layer on said substrate.

A third aspect of the present invention relates to a process for forming a redistribution layer in an electronic component comprising: providing a substrate; depositing a siloxane epoxy prepolymer film onto said substrate; pressing an imprint template having a pattern thereon onto said siloxane epoxy prepolymer film to form an imprint template/siloxane epoxy prepolymer stack, wherein said patterned soft mold has a conformal coating thereon comprising a polymer comprising a repeating unit of formula (IX):

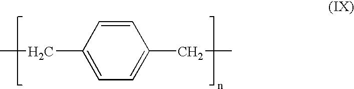

wherein in is 2,000 to 4,000;
exposing the imprint template/siloxane epoxy prepolymer film stack to radiation; and removing the patterned imprint template to form a redistribution layer having an inverse pattern of said patterned imprint template.

A fourth aspect of the present invention relates to a semiconductor device comprising a semiconductor substrate, one or more metal layers or structures located on said substrate, and one or more distribution layers, wherein at least one distribution layer comprises a siloxane epoxy polymer comprising the following repeating units of formulae (X) and (XII):

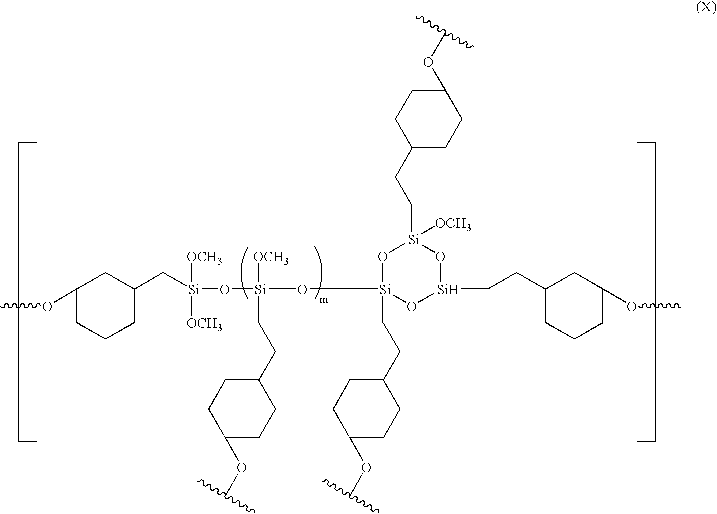

wherein m is an integer ranging from 5 to 50;

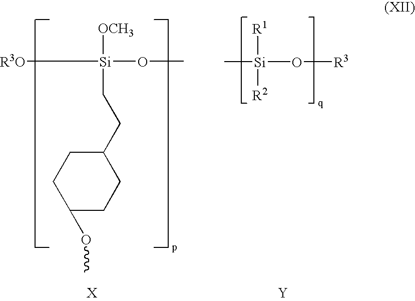

wherein X and Y are units randomly distributed or occurring together; R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from 1 to 50.

### BRIEF DESCRIPTION OF THE DRAWINGS

FIG. 1 depicts two SEM images of patterned redistribution layers, in accordance with the present invention;

FIG. 2 depicts four SEM images of a patterned distribution layer wherein the pattern has a dimension in the micro range, in accordance with the present invention; and

FIG. 3 depicts six SEM images of a patterned distribution layer, in accordance with the present invention.

### DETAILED DESCRIPTION OF THE INVENTION

Throughout this specification the terms and substituents are defined when first introduced and retain their definitions.

The term semiconductor substrate refers to substrates known to be useful in semiconductor devices, i.e., intended for use in the manufacture of semiconductor components, including, but not limited to, focal plane arrays, opto-electronic devices, photovoltaic cells, optical devices, transistor-like devices, 3-D devices, silicon-on-insulator devices, super lattice devices, and the like. Semiconductor substrates include integrated circuits in the wafer stage having one or more layers of wiring, as well as integrated circuits before the application of any metal wiring. Furthermore, a semiconductor substrate can be as simple as the basic wafer used to prepare semiconductor devices. The most common such substrates used at this time are silicon, silicon oxide on silicon, gallium arsenide, germanium, germanium oxide, cadmium, telluride, indium phosphide, silicon carbide, and gallium nitride. A redistribution layer, is also encompassed by the term semiconductor substrate.

The term conformal coating refers to a coating that conforms, i.e., is similar to, when applied to an object to the entire configuration of the object coated. The object may have features in two and/or three dimensions.

The term patternwise refers to exposing a film to radiation such that a chemical transformation is induced that renders the solubility of the exposed regions of the films different from that of the unexposed areas when the films are treated with an appropriate developer.

A process for forming a redistribution layer is presented in accordance with present invention. The process comprises providing a substrate; depositing a siloxane epoxy prepolymer film onto the substrate and then laying an imprint template having a pattern thereon onto the siloxane epoxy prepolymer film to form an imprint template/siloxane epoxy prepolymer stack; exposing the imprint template/siloxane epoxy prepolymer film stack to radiation; then removing the patterned imprint template to form a redistribution layer having an inverse pattern of the patterned imprint template.

In an embodiment of the present invention, the substrate is a semi-conductor substrate. In another embodiment, the substrate is a UV transparent material such as quartz, CaF₂, BaF₂, and sapphire. A siloxane epoxy prepolymer film having a thickness in a range from about 200 nm to about 10 μm is deposited onto the substrate. The thickness of the deposited siloxane epoxy prepolymer film varies according to a particular application and any thickness recognized by one skilled in the art suitable for use in accordance with present invention is included herein. The method of siloxane epoxy prepolymer film deposition includes spin casting (also referred to herein as “spin coating”), dip coating, roller coating, or doctor blading. Typically, spin casting is used to deposit the siloxane epoxy prepolymer film.

The siloxane epoxy prepolymers suitable for use in the present process include those commercially available from Polyset Company, Inc. as PC 2000, PC 2003, PC 2000HV, each of which has the following formula (I):

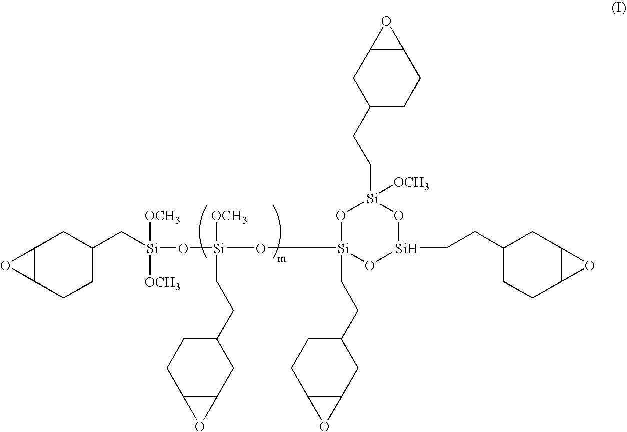

wherein m is an integer from 5 to 50. The molecular weights of these polymers range from about 1000 to about 10,000 g/mole.

Other suitable siloxane epoxy polymers for use in the present invention include random and block copolymers having the following general following formula (II):

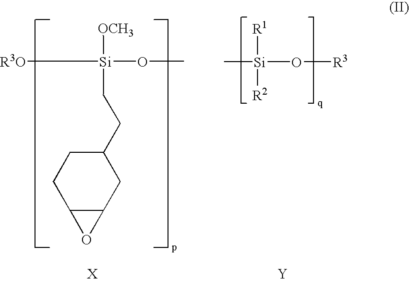

wherein the X monomer units and Y monomer units may be randomly distributed in the polymer chain. Alternatively, like repeating units, X and Y, respectively, may occur together in a block structure. The polymers of formula (II) are advantageous because they have unexpectedly low dielectric constants of less than 3.

In one embodiment, in formula (II), R¹ and R² are each independently methyl, methoxy, ethyl, ethoxy, propyl, butyl, pentyl, octyl, phenyl, and fluoroalkyl and R³ is methyl or ethyl. In addition, p is an integer ranging from 2 to 50 and q is 0 or an integer ranging from 1 to 50. In another embodiment, R³ in the terminal residues at the end of the polymer chain is methyl, resulting in a polymer having formula (IIA):

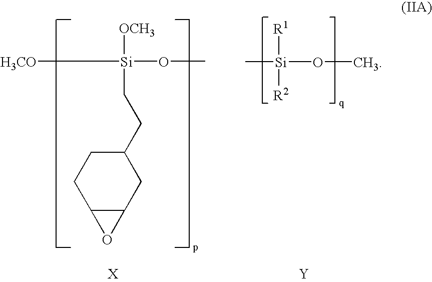

In other embodiments, prepolymers having formula (IIA) include, but are not limited to, Polyset's PC 2010, PC 2021, PC 2026, and PC 2031. In PC 2010, R¹ and R² in formula (IIA) are both phenyl groups, and the ratio of p to q ranges from about 8:1 to about 1:1, but is usually about 4:1 to about 2:1. The molecular weight of PC 2010 ranges from about 5000 to about 7500 g/mole. In PC 2021, R¹ and R² are both methyl groups, as shown in formula (IIB), and the ratio of p to q ranges from about 8:1 to about 1:1, but is usually about 4:1 to about 2:1.

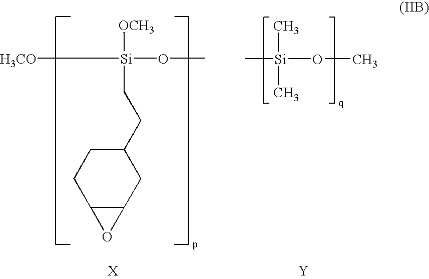

The molecular weight of PC 2021 ranges from about 2000 to about 7500 g/mole. In PC 2026, R¹ is trifluoropropyl, and R² is a methyl group. The ratio of p:q is typically about 3:1. The molecular weight of PC 2026 ranges from about 5000 to about 7500 g/mole. In PC 2031, R¹ is a methyl group, and R² is a propyl group, and the ratio of p to q ranges from about 8:1 to about 1:1, but is usually about 4:1 to about 2:1. The molecular weight of PC 2031 ranges from about 2000 to about 7500 g/mole. The procedure for the synthesis of siloxane epoxy polymers of formula (II), (IIB), and (IIA) containing monomer units X and Y is described fully in U.S. Pat. Nos. 6,069,259; 6,391,999; and 6,832,036, the entire contents of the foregoing are incorporated herein by reference.

The siloxane epoxy prepolymer film that is deposited on the substrate comprises: a siloxane epoxy prepolymer as described supra; a cationic polymerization initiator; and optionally a photosensitizer. Additionally, the siloxane epoxy prepolymer film may comprise a combination of one or more of the foregoing siloxane epoxy prepolymers. Further the siloxane epoxy prepolymer film includes a solvent such as mesitylene. In an embodiment of the present invention, a solvent that is capable of dissolving the siloxane epoxy prepolymer and other components of the siloxane epoxy prepolymer film, is capable for use as a component of the siloxane epoxy prepolymer film.

In one embodiment, cationic polymerization initiators suitable for use in the present invention include diaryliodonium salts selected from the group having formulae (III), (IV), (V), (VI), and (VII):

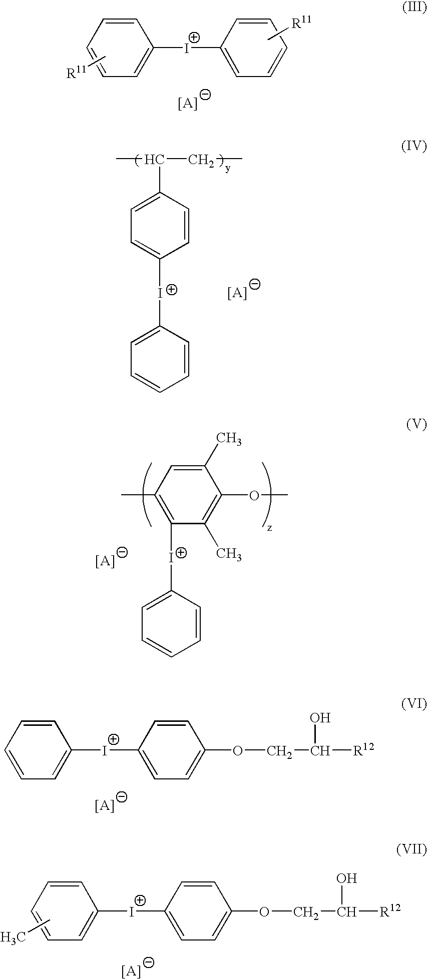

wherein each R¹¹ is independently hydrogen, C₁ to C₂₀ alkyl, C₁ to C₂₀ alkoxyl, C₁ to C₂₀ hydroxyalkoxyl, halogen, and nitro; R¹² is C₁ to C₃₀ alkyl or C₁ to C₃₀ cycloalkyl; y and z are each independently integers having a value of at least 5; [A]⁻ is a non-nucleophilic anion, commonly [BF₄]⁻, [PF₆]⁻, [AsF₆]⁻, [SbF₆]⁻, [B(C₆F₅)₄]⁻, or [Ga(C₆F₅)₄]⁻. The aforementioned diaryliodonium salt curing agents are described in U.S. Pat. Nos. 4,842,800; 5,015,675; 5,095,053; 5,073,643; and 6,632,960, the entire contents of the foregoing are incorporated herein by reference.

In another embodiment, diaryliodonium salts that may be used in accordance with the present invention include [4-(2-hydroxy-1-tetradecyloxy)-phenyl]phenyliodonium hexafluoroantimonate having formula (VI), wherein [A]⁻ is [SbF₆]⁻, and R¹² is C₁₂H₂₅ (available from Polyset Company, as PC-2506); [4-(2-hydroxy-1-tetradecyloxy)-phenyl]phenyliodonium hexafluorophosphate, wherein in formula (VI), [A]⁻ is [PF₆]⁻, and R¹² is C₁₂H₂₅ (available from Polyset Company as PC-2508); [4-(2-hydroxy-1-tetradecyloxy)-phenyl]-4-methylphenyliodonium hexafluoroantimonate (formula (VII)), wherein [A]⁻ is [SbF₆]⁻, and R¹² is C₁₂H₂₅ (available from Polyset Company as PC-2509), and [4-(2-hydroxy-1-tetradecyloxy)-phenyl]-4-methylphenyliodonium hexafluorophosphate (formula (VII)) wherein [A]⁻ is [PF₆]⁻, and R¹² is C₁₂H₂₅ (available from Polyset Company as PC-2519). The preparation of cationic initiators having formula (VII) is described in the aforementioned U.S. Pat. No. 6,632,960.

The wavelength sensitivity of the siloxane epoxy prepolymer film can be adjusted through the use of a photosensitizer. Examples of a photosensitizer that may be used include but are not limited to anthracene, 9,10-di-n-butoxyanthracene (DBA), 9-n-butoxyanthracene, 9-n-decyloxyanthracene, 9,10-di-n-propoxyanthracene, 1-ethyl-9,10-di-n-methoxyanthracene, pyrene, 1-decyloxypyrene, 3-decyloxyperylene, pyrene-1-methanol, 9-methylcarbazole, 9-vinylcarbazole, 9-ethylcarbazole, poly(9-vinylcarbazole), phenothiazine, 9-decylphenothiazine, and the like.

The cationic polymerization initiator is dissolved in 3,4-epoxycyclohexylmethyl-3′,4′-epoxycyclohexane carboxylate, dicyclopentadiene dioxide, or bis(3,4-epoxycyclohexyl)adipate to form a catalyst solution which contains from about 20 parts by weight to about 60 parts by weight of the selected cationic initiator and from about 40 to about 80 parts by weight of 3,4-epoxycyclohexylmethyl-3′,4′-epoxycyclohexane carboxylate, dicyclopentadiene dioxide, or bis(3,4-epoxycyclohexyl)adipate. The catalyst solution typically contains about 40 parts by weight of the diaryliodonium salt and about 60 parts by weight 3,4-epoxycyclohexylmethyl-3′,4′-epoxycyclohexane carboxylate, dicyclopentadiene dioxide, or bis(3,4-epoxycyclohexyl)adipate.

About 1 part by weight to about 5 parts by weight of the catalyst solution is added to an appropriate amount of siloxane epoxy prepolymer (typically ranging from about 95 to about 99.9 parts by weight).

A formulation of the siloxane epoxy prepolymer film in an embodiment of the present invention is listed below:

| Material | Pbw |
|---|---|
| Polyset PC-2000 HV | 60 |
| 1,3,5-trimethylbenzene (mesitylene) | 38 |
| Polyset PC-2506 | 1.8 |
| (40% bw PC-2506/60% bw 3,4-epoxycyclohexylmethyl | |
| 3′,4′-epoxycyclohexanecarboxylate) | |
| 9,10 DBA | 0.2 |

In an embodiment of the present invention, the siloxane epoxy prepolymer is in a range from about 40 parts by weight to about 70 parts by weight; the solvent is in a range from about 20 parts by weight to about 50 parts by weight; the catalyst solution is in a range from about 1 parts by weight to about 5 parts by weight; and the photosensitizer is a range from about 0.1 parts by weight to about 1 parts by weight.

After the siloxane epoxy prepolymer film is deposited, an imprint template is laid onto the siloxane epoxy prepolymer film resulting in the formation of an imprint template/siloxane epoxy prepolymer stack. The imprint template has a pattern thereon having at least one dimension between 1.0 nm and 10 μm. In one embodiment, the dimension is between 1.0 nm and 100 nm. In other embodiments, the dimension is between 100 nm and 0.5 μm, and between 0.5 μm and 10 μm. The at least one dimension varies from a lower limit of 1.0 nm, 10 nm, or 50 nm to an upper limit of 1 μm, 5 μm, or 10 μm. All of the aforementioned ranges are inclusive and combinable.

A hard mold is used to fabricate the imprint template with the hard mold first fabricated via a photolithography process; see discussion infra. Alternatively, the hard mold may be commercially available for purchase. The hard mold, whether fabricated or purchased, has a pattern thereon having at least one dimension between 1.0 nm and 10 μm. In one embodiment, the dimension is between 1.0 nm and 100 nm. In other embodiments the dimension is between 100 nm and 0.5 μm, and between 0.5 μm and 10 μm. The at least one dimension varies from a lower limit of 1.0 nm, 10 nm, or 50 nm to an upper limit of 1 μm, 5 μm, or 10 μm. All of the foregoing ranges are inclusive and combinable.

The hard mold may be fabricated by a photolithography process or an E-beam writing process. The photolithography process entails providing a semiconductor substrate, as described supra, such as silicon oxide on silicon substrate. A siloxane epoxy prepolymer film is deposited onto the silicon oxide on silicon substrate. The methods of deposition are described supra. Typically the siloxane epoxy prepolymer film is applied via spin casting. Prior to deposition of the siloxane epoxy prepolymer an adhesion promoter layer may first be deposited. An example of an adhesion promoter is hexamethyldisilizane (HMDS). In an embodiment of the present invention, other adhesion promoters recognized by one skilled in the art capable of promoting adhesion between a substrate and a material applied thereon is capable of use in accordance with the present invention.

A pattern on a photomask is then transferred to the siloxane epoxy prepolymer/substrate by passing actinic radiation through the patterned photomask, i.e., the siloxane epoxy prepolymer is patternwise exposed to radiation. The pattern transfer step is then followed up with RIE. Photolithography is used to fabricate hard molds having a pattern thereon having at least one dimension in the micron range or less. Direct E-beam lithography is used to form hard molds with patterns thereon having at least one dimension in the submicron range, i.e., 100 nm or less.

The imprint template is fabricated by spin-casting a siloxane prepolymer having a thickness in a range from about 200 nm to about 10 μm, such as polydimethylsiloxane (PDMS) resin, on to the hard mold and followed by thermally curing the siloxane prepolymer/hard mold stack to give a siloxane polymer/hard mold stack. The siloxane polymer is then released from the hard mold resulting in an imprint template comprising the siloxane polymer and has a pattern thereon that is an inverse of the pattern on the hard mold.

The siloxane prepolymers suitable for use in fabrication of the imprint template include PDMS resin, the compounds of formula (I) and (II), and the polymerizable siloxane oligomers having the structure of Formula I as defined in U.S. Pat. No. 6,069,259, the entire contents of which are incorporated herein by reference.

After formation of the imprint template/siloxane epoxy prepolymer stack, the entire stack is put under a vacuum to provide a hydraulic force to press the imprint template into the siloxane prepolymer. It is recognized that any vacuum low enough to provide a strong enough force to press the imprint template into the siloxane prepolymer is suitable for use in the present invention. The stack then is exposed to radiation. Examples of radiation include thermal radiation, i.e. heat, and actinic radiation, such as U.V, visible, or electron beam. In one embodiment of the present invention, exposure to radiation results in the curing of the siloxane epoxy prepolymer to a siloxane epoxy polymer comprising the following repeating units:

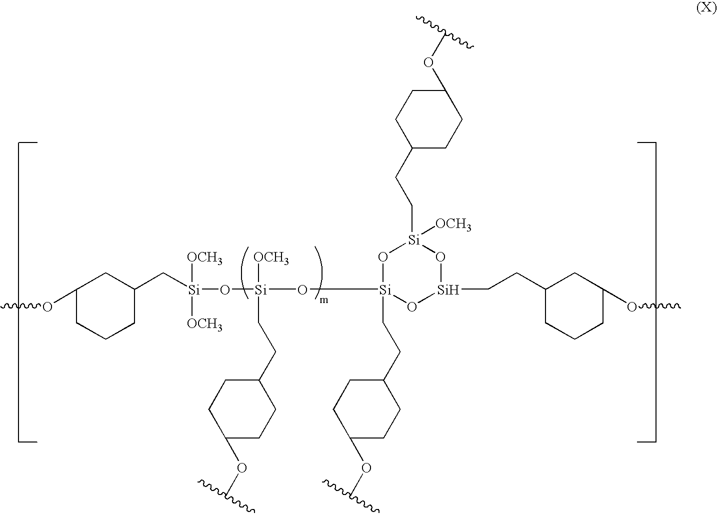

wherein m is an integer ranging from 5 to 50;

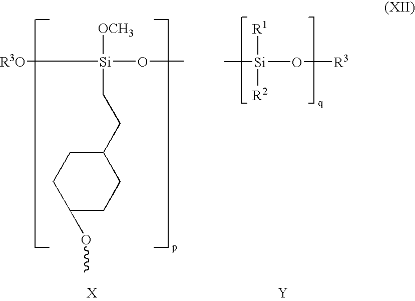

wherein X and Y are units randomly distributed or occurring together; R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from 1 to 50. Other forms of radiation recognized by one skilled in the art capable of curing the siloxane epoxy prepolymer may be used in accordance with present invention.

Depending on the thickness of the siloxane epoxy prepolymer film, thermal curing is generally performed by heating the deposited film to a temperature ranging from about 155° C. to about 360° C., typically about 165° C., for a period of time ranging from about 0.5 hour to about 2 hours. Siloxane epoxy prepolymer films that are curable by U.V. light are flood exposed by U.V. light (>300 mJ/cm²@250-380 nm). Curing by E-beam radiation is often done at a dosage ranging from about 3 Mrad to about 12 Mrad.

Often a thermal bake is used in conjunction with U.V. or E-beam radiation curing. Direct E-beam curing is described in U.S. Pat. Nos. 5,260,349 and 4,654,379; the entire contents of the foregoing patents are incorporated herein by reference. The formulation of a particular siloxane epoxy prepolymer film will determine which curing method will be used, as would be recognized by one skilled in the art. Following curing, a thermal anneal optionally is employed under nitrogen or another inert gas at temperatures ranging from about 200° C. to about 300° C., but typically about 250° C. for a period of time ranging from about 1 hour to about 3 hours. Typically the time is about 2 hours. Furthermore, by changing the formula of the siloxane epoxy prepolymer, by varying its concentration in the film, and/or the thickness of the deposited film, the onset curing temperature and the speed of cure can be adjusted within a wide latitude. Curing of the polymer also is affected in the presence of a cationic polymerization initiator as described supra.

Typically, when the siloxane epoxy polymer films are thermally cured, the amount of catalyst needed can be decreased dramatically relative to the amount of catalyst needed to affect a cure induced by actinic radiation. For example, under thermal curing, a siloxane epoxy prepolymer film contains about 0.1 wt. % cationic initiator (i.e. 0.1 parts by weight catalyst solution and about 99.9 parts by weight siloxane epoxy prepolymer) wherein the catalyst solution is 40 wt. % of [4-(2-hydroxy-1-tetradecyloxy)-phenyl]phenyliodonium hexafluoroantimonate (Polyset PC-2506) dissolved in 3,4-epoxycyclohexylmethyl 3′,4′-epoxycyclohexanecarboxylate (Union Carbide ERL-4221E)). By contrast, when curing is done by photo-irradiation, the amount of the catalyst is generally about 4 wt. % (i.e. 4 parts by weight catalyst solution and 96 parts polymer).

A second process for forming a redistribution layer is presented in accordance with present invention. The process comprises providing a substrate and depositing a siloxane epoxy prepolymer film onto the substrate, then patternwise exposing the epoxy prepolymer film to actinic radiation and developing the film so as to form a patterned redistribution layer. Substrates, siloxane epoxy prepolymer films, and actinic radiation suitable for use in accordance with the present invention are described supra. The siloxane epoxy prepolymer film is deposited onto a substrate via techniques also previously described. Typically, the siloxane epoxy prepolymer film is deposited via spin casting.

The siloxane epoxy prepolymer film is then exposed to actinic radiation that first passes through a photomask. The photomask is an opaque plate with holes or transparencies that allow radiation to shine through in a defined pattern onto a substrate, i.e., the siloxane epoxy prepolymer film. Typically the photomask is a transparent fused silica blank covered with a pattern defined with a chrome metal absorbing film. Areas of the prepolymer film exposed to the radiation are thus cured resulting in the formation of a siloxane epoxy polymer. The polymer formed is the comprising repeating units of formula (X), (XI), and (XII) described supra. After patternwise exposure to radiation, the siloxane epoxy prepolymer film is developed by washing with an appropriate solvent revealing the radiation-cured pattern, i.e., the patterned redistribution layer.

Examples of developing solvents that are used in an embodiment of the present invention include acetone, xylene, or any solvent that is recognized by one skilled in the art capable of selectively removing the unexposed siloxane epoxy prepolymer film while leaving behind the siloxane epoxy polymer. The patterned redistribution layer formed has at least one dimension between 1.0 nm and 10 μm. In one embodiment, the dimension is between 1.0 nm and 100 nm. In other embodiments, the dimension is between 100 nm and 0.5 μm, and between 0.5 μm and 10 μm. The at least one dimension varies from a lower limit of 1.0 nm, 10 nm, or 50 nm to an upper limit of 1 μm, 5 μm, or 10 μm. All of the aforementioned ranges are inclusive and combinable.

A third process for forming a redistribution layer is presented in accordance with present invention. The process comprises providing a substrate, then depositing a siloxane epoxy prepolymer film onto the substrate and pressing an imprint template having a pattern thereon onto the siloxane epoxy prepolymer film to form an imprint template/siloxane epoxy prepolymer stack. The patterned imprint template has a conformal coating comprising a polymer comprising repeating units of formula (IX), hereon referred to as parylene-N:

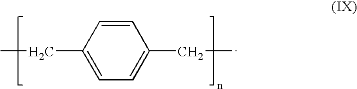

The variable n is in a range between 2,000 and 4,000. The imprint template/siloxane epoxy prepolymer film stack is exposed to radiation. The patterned imprint template is then removed to form a redistribution layer having an inverse pattern of the patterned imprint template.

The methodology for this process for forming a distribution layer is the same as described supra for the first process for forming a distribution layer with two differences. The first difference is that the patterned imprint template of this process has a conformal coating of parylene-N thereon. The second difference is that a vacuum is not needed to ultimately press the imprint template into the siloxane epoxy prepolymer film. In this embodiment, a mechanical means is used to provide the force to press the imprint template into the siloxane epoxy prepolymer film.

The imprint template is fabricated by providing a template having a pattern thereon. The pattern has at least one dimension between 1.0 nm and 10 μm. In one embodiment, the dimension is between 1.0 nm and 100 nm. In other embodiments, the dimension is between 100 nm and 0.5 μm, and between 0.5 μm and 10 μm. The at least one dimension varies from a lower limit of 1.0 nm, 10 nm, or 50 nm to an upper limit of 1 μm, 5 μm, or 10 μm. All of the aforementioned ranges are inclusive and combinable.

The patterned template may be commercially available for purchase or fabricated by methods in the processes described supra for the hard mold and imprint template. A conformal parylene coating is deposited on the patterned face of the template using the Gorham method described in W. Gorham, J. Polym. Sci., Part A-1, 4, 3027 (1966), the entire contents of which are incorporated herein by reference, and polymerized to form a parylene-N. The template comprises a material that is transparent to actinic radiation, typically transparent to UV light. In another embodiment of the present invention, the substrate comprises a material that is transparent to actinic radiation.

The patterned imprint template having the conformal coating of parylene-N thereon has an advantage of being easily removed from the siloxane epoxy prepolymer after exposing the soft mold/siloxane epoxy prepolymer stack to radiation.

A semiconductor device is presented in accordance with the present invention. The semiconductor device comprises a semiconductor substrate; one or more metal layers or structures located on the substrate, and one or more distribution layers. At least one distribution layer comprises a siloxane epoxy polymer selected from the group consisting of polymers comprising the following repeating units:

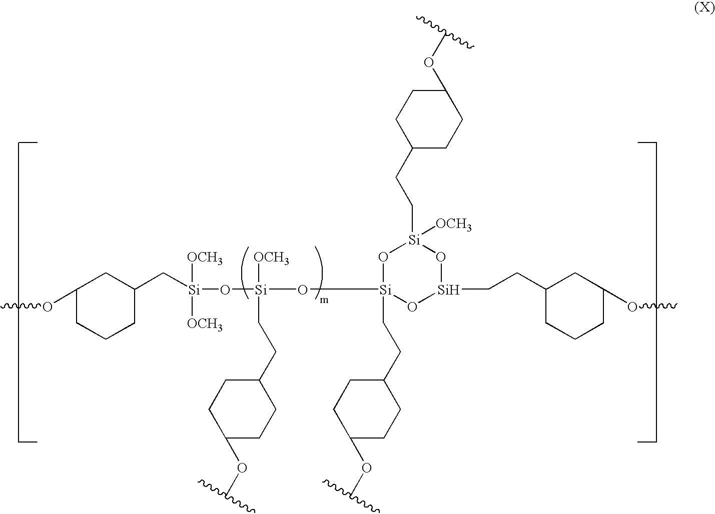

wherein m is an integer ranging from 5 to 50; and

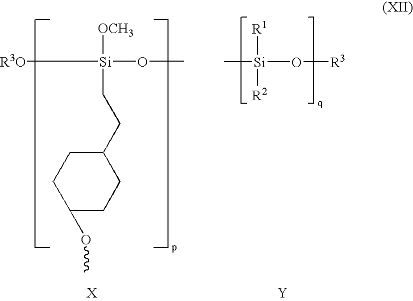

wherein X and Y are units randomly distributed or occurring together; R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from 1 to 50.

The at least one distribution layer has a pattern thereon that has at least one dimension between 1.0 nm and 10 μm. In one embodiment, the dimension is between 1.0 nm and 100 nm. In other embodiments, the dimension is between 100 nm and 0.5 μm, and between 0.5 μm and 10 μm. The at least one dimension may vary from a lower limit of 1.0 nm, 10 nm, or 50 nm to an upper limit of 1 μm, 5 μm, or 10 μm. All of the aforementioned ranges are inclusive and combinable.

In an embodiment of the present invention, a conformal coating of parylene-N is used in contact lithography. Also known as contact printing, an image to be printed is obtained by illumination of a photomask in direct contact with a substrate coated with an imaging photoresist layer. The substrate used is as defined supra. Imaging photoresist layers comprise the siloxane epoxy prepolymers also described supra.

Parlyene-N is conformally coated onto a photomask. The side of the photomask having the parylene-N is brought into contact with photoresist layer prior to illumination with radiation. After illumination, the photomask is removed from the cured photoresist layer. An advantage of using a photomask conformally coated with parylene-N is that removal of the photomask does not result in it sticking to the cured photoresist layer. Photomasks capable of use in accordance with the present invention include but are not limited to binary intensity amplitude mask, light coupling mask, and hybrid nanoimprint-contact mask.

The following examples are given by way of illustration and are not intended to be limitative of the present invention. The reagents and other materials used in the examples are readily available materials, which can be conveniently prepared in accordance with conventional preparatory procedures or obtained from commercial sources.

### EXAMPLES

### Example 1

### Fabrication of a Redistribution Layer Via Photolithography

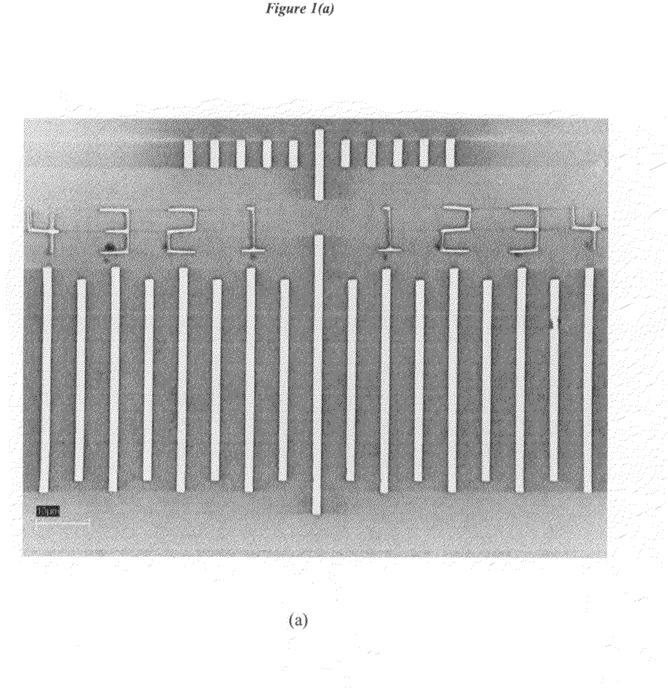

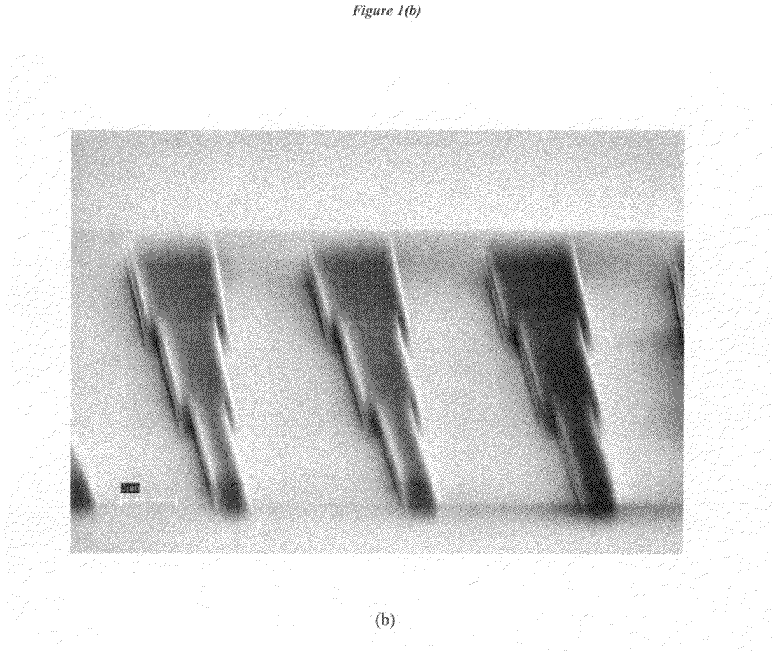

Eight-inch silicon wafers are used as substrates. They are RCA cleaned via standard procedures recognized by one skilled in the art and an adhesion promoter, such as hexamethyldisilizane (HMDS), is spin-coated onto each wafer at 3000 rpm for 40 sec. A siloxane epoxy prepolymer film, as described supra, is spin-coated onto each wafer at 3000 rpm for 100 sec to a thickness of 3 μm. The siloxane epoxy prepolymer films are subjected to I-line patternwise UV exposure using a GCA 5× stepper (resolution to 0.9 μm) through a photomask. The film then was developed in acetone where the developer washes away the unexposed area of the siloxane epoxy prepolymer films to reveal the UV cured pattern comprising a siloxane epoxy polymer. The development stage is followed by a post-development bake for 1 hr@165° C. and then blowing dry with nitrogen gun. FIG. 1 shows two SEM images (a) and (b) of the developed patterned redistribution layer on silicon substrates. It is noted that the straight sidewalls of the patterns result from the good photo-definition characteristics of the siloxane epoxy prepolymer. The scale bars for image (a) and (b) are 10 μm and 2 μm respectively.

### Example 2

### Formation of a Redistribution Layer Via Micro-Imprinting

A hard mold is first fabricated using a photolithography process. A siloxane epoxy prepolymer film, as described supra, is deposited onto a silicon oxide/silicon substrate and through photolithography a pattern on a photomask is transferred onto a siloxane epoxy prepolymer film. The pattern transfer step then is followed by reactive ion etching (RIE).

An imprint template is fabricated by casting a poly(dimethyl)siloxane (PDMS) resin on the hard mold and is followed by curing the PDMS/hard mold stack in oven at 150° C. for 30 min. The cured PDMS then is released from the hard mold resulting in an imprint template having a pattern that is the inverse of the pattern on the hard mold.

Silicon wafer pieces, 2-inches or larger, are used as substrates. After standard RCA cleaning an adhesion promoter (HMDS) is spin-coated onto each wafer at 3000 rpm for 40 sec. Then a siloxane epoxy prepolymer film is spin-coated onto each wafer at 3000 rpm for 100 sec to a thickness of 6 μm. The imprint template, previously fabricated, is gently laid on the siloxane epoxy prepolymer film and the imprint template/siloxane epoxy prepolymer film stack is put in a vacuum chamber under a vacuum of 10-3 torr for 5 min. This step provides a hydraulic force to press the soft mold into the siloxane epoxy prepolymer film. The stack then is subjected to broadband UV exposure under 8 mW for 12 sec using a Karl Zeiss aligner. The imprint template is released leaving a pattern on the siloxane epoxy prepolymer film that is inverse to the pattern of the imprint template. A post-release bake of 1 hour at 165° C. is performed. Lastly, a residual imprint layer in the depressed areas is removed via RIE.

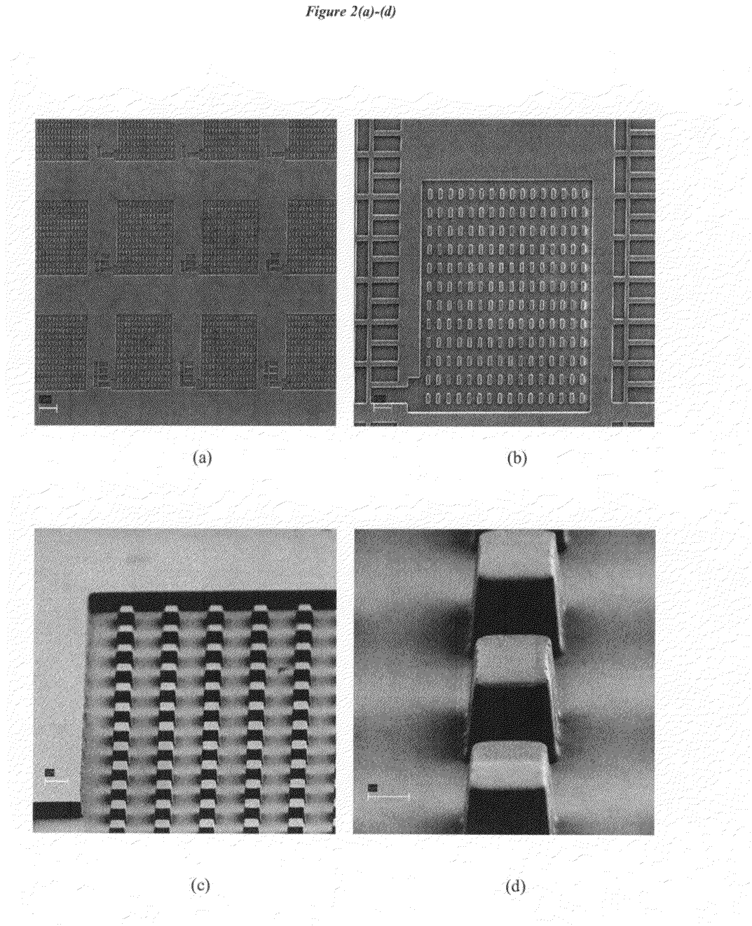

FIG. 2 shows SEM images (a), (b), (c), and (d) of a redistribution layer having micro imprinted patterns thereon. The scale bars for image (a)-(d) are 30 μm, 10 μm, 3 μm, and 1 μm respectively.

### Example 3

### Formation of a Redistribution Layer Via Nano-Imprinting

A hard mold with sub-micron feature size, i.e., nano, is first fabricated using a direct E-beam writing process. A resist for E-beam writing is deposited on a substrate via spin casting, as described supra, onto a silicon oxide/silicon substrate. A pattern having at least one dimension 100 nm or less is transferred to the substrate using a Zeiss supra FE-SEM and is followed by RIE.

An imprint template is fabricated following the procedure described in example 2. The subsequent nano-imprinting process follows the same procedure as the micro-imprinting process in example 2 except that the redistribution layer formed in the present example has an imprinted pattern having at least on dimension measuring 100 nm or less. The foregoing process is compatible for use with a nano-imprinting tool such as an EVG® aligner.

### Example 4

### Formation of a Redistribution Layer Via Imprinting

A 5 nm film of parylene-N is deposited conformally on a commercial imprint template that is UV transparent. Poly(p-xylylene) is deposited using the Gorham method. A detailed description of the reactor and deposition process is described in J. B. Fortin, and T.-M. Lu, J. Vac. Sci. Technol. A, 18 (5) 2459 (2000), the entire contents of which are incorporated herein by reference. Briefly, the reactor consists of a sublimation furnace, a pyrolysis furnace, and a bell jar type deposition chamber. The base pressure in the deposition chamber is at mid 10⁻⁶ Torr. During growth the deposition chamber pressure is at 2.0 mTorr yielding deposition rates about 13.5 Å/min.

The precursor [2,2]paracyclophane is sublimed at a temperature of 155° C. and the pressure is controlled by a heated valve and measured by a heated capacitance manometer located in the deposition chamber. The sublimed precursor passes into a high temperature region (650° C.) of the reactor inlet where it is cleaved into two p-xylylene monomers by vapor phase pyrolysis. These reactive intermediates are then transported to a room temperature deposition chamber where upon physisorption onto the template free radical polymerization takes place. Thus a conformal coating of linear chains of poly(p-xylylene), i.e., parylene-N is formed on the template having unterminated end groups.

After the imprint template is conformally coated with parylene-N, the coated template is hereon referred to as a patterned soft mold, the imprint process proceeds. First, an imprint resist such, as siloxane epoxy prepolymer film is spin-coated onto the substrate. The patterned imprint template is then pressed into the siloxane epoxy prepolymer film and the patterned imprint template/siloxane epoxy prepolymer film stack is subjected to UV illumination through the UV transparent soft mold to cure the underlying siloxane epoxy prepolymer film. The patterned imprint template is removed from the underlying film forming a redistribution layer having a pattern that is the inverse of the soft mold pattern. Lastly, a residual imprint layer in the depressed areas is removed via RIE.

### Example 5

### Formation of a Redistribution Layer Via Imprinting

An imprint template having a conformal coating of parylene-N is fabricated as described in example 4. The substrate for the imprint template does not comprise a UV transparent material but instead comprises silicon oxide on silicon. A siloxane epoxy prepolymer film is spin-coated onto a glass substrate that is UV transparent. The imprint template is then pressed into the siloxane epoxy prepolymer film and the imprint template/siloxane epoxy prepolymer film stack is subjected to UV illumination. Illumination is occurs through the glass substrate to cure the underlying film. The patterned imprint template is removed from the underlying film forming a redistribution layer having a pattern that is the inverse of the soft mold pattern. Lastly, a residual imprint layer in the depressed areas is removed via RIE.

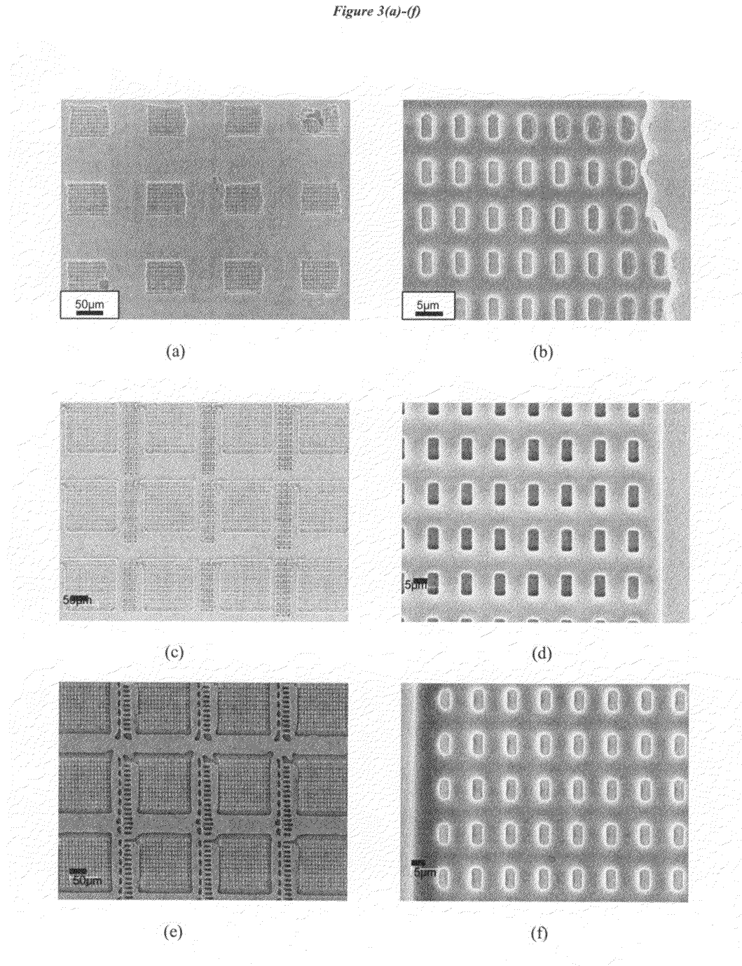

FIG. 3, (a) and (b) are SEM images of a redistribution layer fabricated using an imprint template without conformal coating polymer (IX). FIG. 3, (c) and (d) are SEM images a redistribution layer fabricated using an imprint template with a conformal coating parylene-N that is 2 nm thick. FIG. 3, (e) and (f) are SEM images a redistribution layer fabricated using an imprint template with a conformal coating of parylene-N that is 5 nm thick.

Example 5 demonstrates the advantages of a patterned imprint template having thereon a conformal coating of parylene-N. The conformal coating allows the patterned imprint template to be easily removed from the siloxane epoxy prepolymer stack after exposing it to radiation and thus preventing defect formation typically resulting from direct contact between an imprint template and a coated substrate.

What is claimed is:

1. A process for forming a redistribution layer in an electronic component comprising:
providing a substrate;
depositing a siloxane epoxy prepolymer film onto said substrate;
laying an imprint template having a pattern thereon onto said siloxane epoxy prepolymer film to form an imprint template/siloxane epoxy prepolymer stack, said pattern having at least one dimension measuring between 1.0 nm and 10 μm;
exposing said imprint template/siloxane epoxy prepolymer film stack to radiation; and
removing said patterned imprint template to form a redistribution layer having an inverse pattern of said patterned soft mold.

2. The process according to claim 1, wherein said substrate is a semi-conductor substrate forming an integrated circuit.

3. The process according to claim 1, wherein said substrate is a semi-conductor material selected from the group consisting of silicon, silicon oxide on silicon, gallium arsenide, germanium, germanium oxide, cadmium telluride, indium, phosphide, silicon carbide, and gallium nitride.

6. The process according to claim 1, wherein the siloxane epoxy prepolymer film comprises:
1) a compound of formula II: 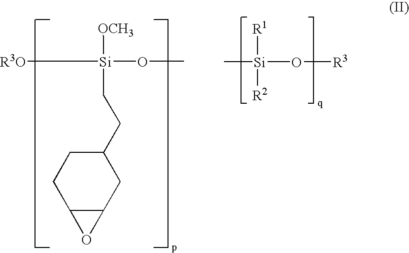
wherein
R¹ and R² are independently selected from the group consisting of methyl, methoxy, ethyl, ethoxy, propyl, butyl, pentyl, octyl, phenyl, and fluoroalkyl;
R³ is methyl or ethyl;
p is an integer from 2 to 50; and
q is 0 or an integer from 1 to 50;
2) a cationic polymerization initiator; and
3) optionally a photosensitizer.

7. A process according to claim 6, wherein said cationic polymerization initiator is selected from the group consisting of diazonium, sulfonium, phosphonium, and iodonium salts.

8. A process according to claim 7, wherein said cation polymerization initiator is an iodonium salt selected from the group consisting of diaryliodonium salts having the formulae (III), (IV), (V), and (VII): 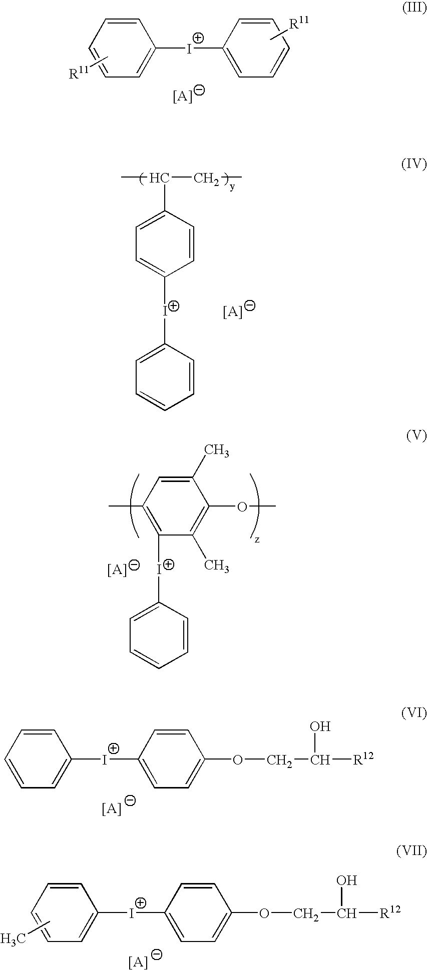
wherein
each R¹¹ is independently hydrogen, C₁ to C₂₀ alkyl, C₁ to C₂₀ alkoxyl, C₁ to C₂₀ hydroxyalkoxyl, halogen, and nitro;
R¹² is C₁ to C₃₀ alkyl or C₁ to C₃₀ cycloalkyl;
y and z are each independently integers having a value of at least 5; and
[A]⁻ is a non-nucleophilic anion selected from the group consisting of [BF₄]⁻, [PF₆]⁻, [AsF₆]⁻, [SbF₆]⁻, [B(C₆F₅)₄]⁻, and [Ga(C₆F₅)₄]⁻.

9. A process according to claim 6, wherein said compound of formula II is a compound of formula I: 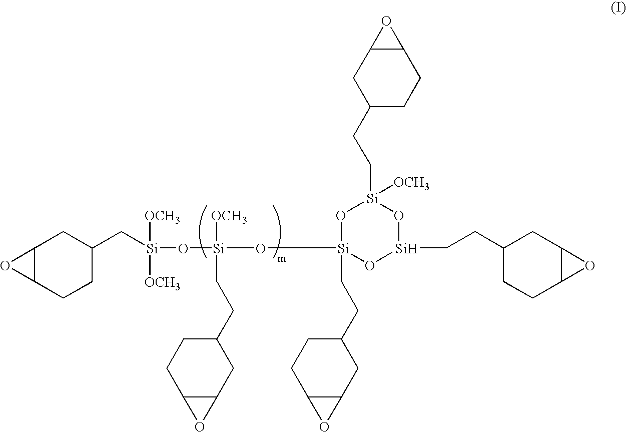
wherein m is an integer from 5 to 50.

10. A process according to claim 6, wherein said compound of formula II is a compound of formula IIa:

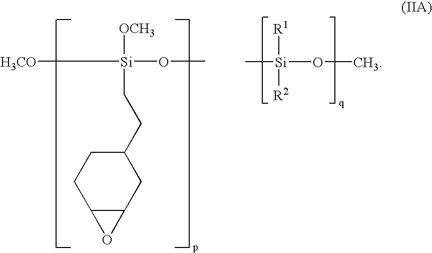

11. A process according to claim 1, wherein said imprint template is formed by a process comprising:
providing a hard mold having a pattern thereon, said pattern having at least one dimension measuring between 1.0 nanometer and 10 microns;
depositing a siloxane epoxy prepolymer onto said hard mold;
curing said siloxane epoxy prepolymer to form an imprint template; and
removing said imprint template from said hard mold, said imprint template having an inverse pattern thereon of said hard mold.

12. A process for forming a redistribution layer in an electronic component comprising:
providing a substrate;
depositing a siloxane epoxy prepolymer film comprising:
1) a compound of formula II: 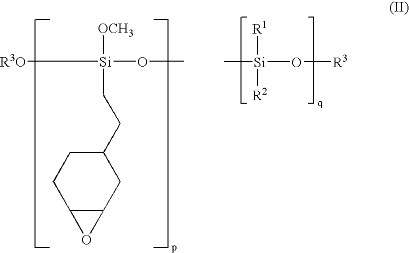
wherein
R¹ and R² are independently selected from the group consisting of methyl, methoxy, ethyl, ethoxy, propyl, butyl, pentyl, octyl, phenyl, and fluoroalkyl;
R³ is methyl or ethyl;
p is an integer from 2 to 50; and
q is 0 or an integer from 1 to 50;
2) a cationic polymerization initiator; and
3) optionally a photosensitizer, onto said substrate;
patternwise exposing said siloxane epoxy prepolymer film to actinic radiation; and
developing said exposed siloxane epoxy prepolymer film so as to form a patterned redistribution layer on said substrate.

13. A process according to claim 12, wherein said cationic polymerization initiator is selected from the group consisting of diazonium, sulfonium, phosphonium, and iodonium salts.

14. A process according to claim 13, wherein said cation polymerization initiator is an iodonium salt selected from the group consisting of diaryliodonium salts having the formulae (III), (IV), (V), and (VII): 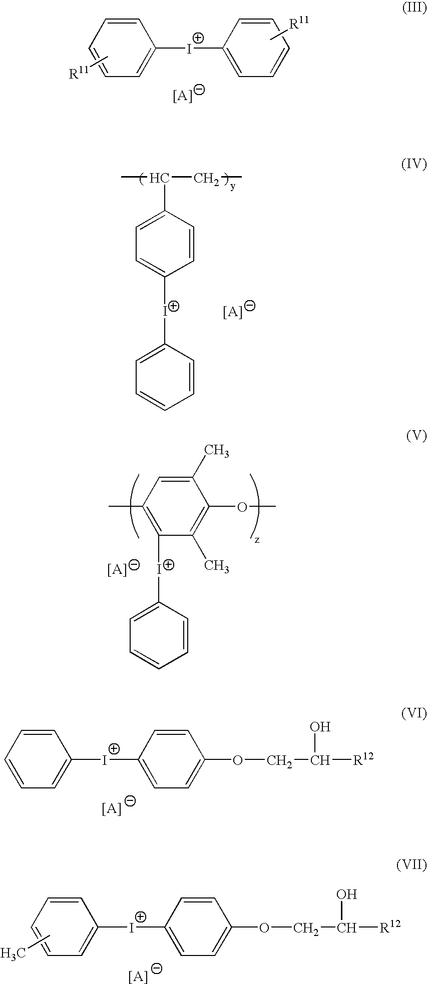
wherein
each R¹¹ is independently hydrogen, C₁ to C₂₀ alkyl, C₁ to C₂₀ alkoxyl, C₁ to C₂₀ hydroxyalkoxyl, halogen, and nitro;
R¹² is C₁ to C₃₀ alkyl or C₁ to C₃₀ cycloalkyl;
y and z are each independently integers having a value of at least 5; and
[A]⁻ is a non-nucleophilic anion selected from the group consisting of [BF₄]⁻, [PF₆]⁻, [AsF₆]⁻, [SbF₆]⁻, [B(C₆F₅)₄]⁻, and [Ga(C₆F₅)₄]⁻.

15. The process according to claim 12, wherein said substrate is a semi-conductor substrate forming an integrated circuit.

16. The process according to claim 12, wherein said substrate is a semi-conductor material selected from the group consisting of silicon, silicon oxide on silicon, gallium arsenide, germanium, germanium oxide, cadmium telluride, indium, phosphide, silicon carbide, and gallium nitride.

17. The process according to claim 12, wherein said compound of formula II is a compound of formula I: 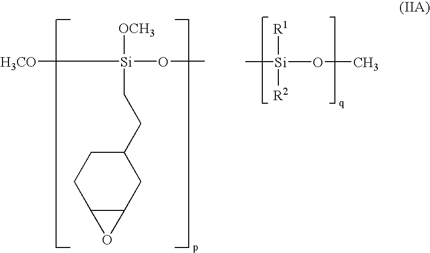
wherein
R¹ and R² are independently selected from the group consisting of methyl, methoxy, ethyl, ethoxy, propyl, butyl, pentyl, octyl, phenyl, and fluoroalkyl;
p is an integer from 2 to 50; and
q is 0 or an integer from 1 to 50.

18. A process according to claim 12, wherein said compound of formula II is a compound of formula I: 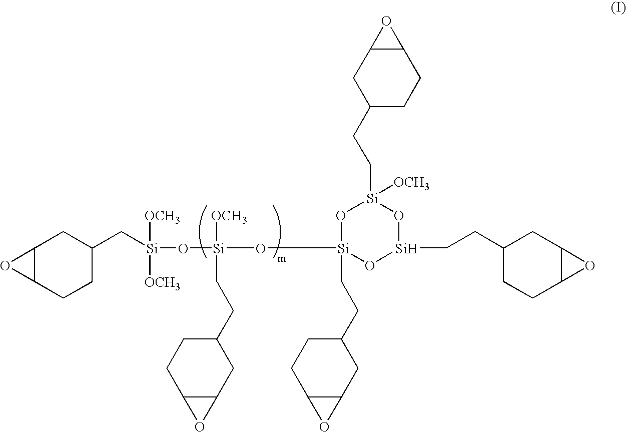
wherein m is an integer from 5 to 50.

19. A process according to claim 12, wherein said pattern has at least one dimension measuring between 1.0 nm and 10 μm.

20. A process for forming a redistribution layer in an electronic component comprising:
providing a substrate;
depositing a siloxane epoxy prepolymer film onto said substrate;
pressing an imprint template having a pattern thereon onto said siloxane epoxy prepolymer film to form an imprint template/siloxane epoxy prepolymer stack, wherein said patterned imprint template has a conformal coating thereon comprising a polymer comprising the repeating unit of formula (IX): 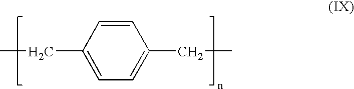
wherein in is 2,000 to 4,000.
exposing said imprint template/siloxane epoxy prepolymer film stack to radiation; and
removing said patterned imprint template to form a redistribution layer having an inverse pattern of said patterned an imprint template.

21. The process according to claim 20, wherein said substrate is a semi-conductor substrate forming an integrated circuit.

22. The process according to claim 20, wherein said substrate is a semi-conductor material selected from the group consisting of silicon, silicon oxide on silicon, gallium arsenide, germanium, germanium oxide, cadmium telluride, indium, phosphide, silicon carbide, and gallium nitride.

23. The process according to claim 20, wherein said siloxane epoxy prepolymer film comprises:
1) a compound of formula II: 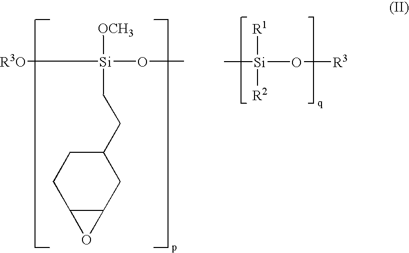
wherein
R¹ and R² are independently selected from the group consisting of methyl, methoxy, ethyl, ethoxy, propyl, butyl, pentyl, octyl, phenyl, and fluoroalkyl;
R³ is methyl or ethyl;
p is an integer from 2 to 50; and
q is 0 or an integer from 1 to 50;
2) a cationic polymerization initiator; and
3) optionally a photosensitizer.

24. A process according to claim 23, wherein said cationic polymerization initiator is selected from the group consisting of diazonium, sulfonium, phosphonium, and iodonium salts.

25. A process according to claim 24, wherein said cation polymerization initiator is an iodonium salt selected from the group consisting of diaryliodonium salts having the formulae (III), (IV), (V), and (VII): 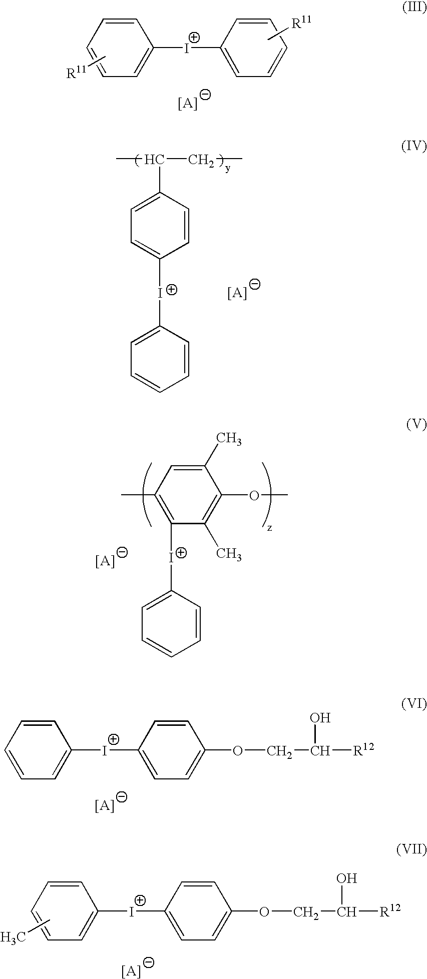
wherein
each R¹¹ is independently hydrogen, C₁ to C₂₀ alkyl, C₁ to C₂₀ alkoxyl, C₁ to C₂₀ hydroxyalkoxyl, halogen, and nitro;
R¹² is C₁ to C₃₀ alkyl or C₁ to C₃₀ cycloalkyl;
y and z are each independently integers having a value of at least 5; and
[A]⁻ is a non-nucleophilic anion selected from the group consisting of [BF₄]⁻, [PF₆]⁻, [AsF₆]⁻, [SbF₆]⁻, [B(C₆F₅)₄]⁻, and [Ga(C₆F₅)₄]⁻.

26. A process according to claim 23, wherein said compound of formula II is a compound of formula I: 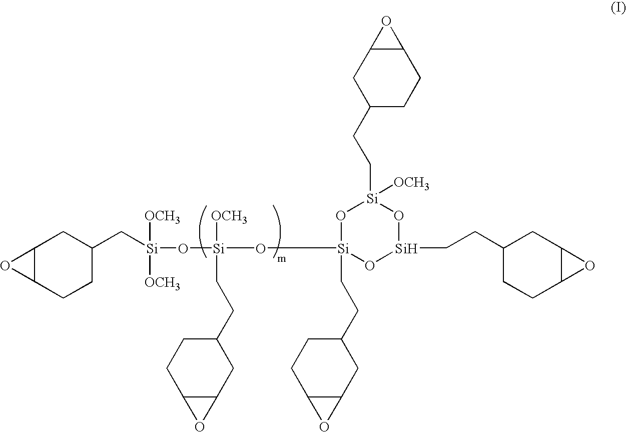
wherein m is an integer from 5 to 50.

27. A process according to claim 23, wherein said compound of formula II is a compound of formula IIa:

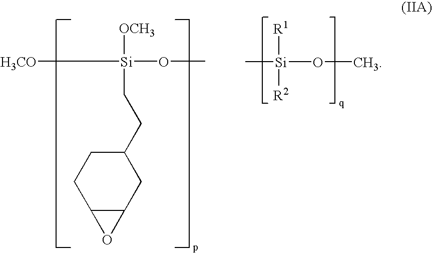

28. A process according to claim 20, wherein said pattern has at least one dimension measuring between 1.0 nm and 10 μm.

29. The process according to claim 20, wherein said substrate comprises a UV transparent material.

30. The process according to claim 20, wherein said imprint template comprises a UV transparent material.

31. The process according to claim 20, wherein said conformal coating with has a thickness between 1 nm and 10 nm.

32. A process according to claim 20, wherein said imprint template is formed by a process comprising:
providing a template having a pattern thereon, said pattern having at least one dimension measuring between 1.0 nanometer and 10 microns;
depositing a conformal parylene prepolymer film onto said template; and
polymerizing said parylene prepolymer film to form an imprint template having a polymer comprising a repeating unit of formula (IX): 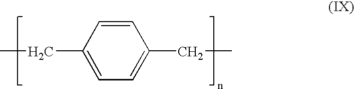
wherein in is 2,000 to 4,000.

33. A semiconductor device comprising a semiconductor substrate, one or more metal layers or structures located on said substrate, and one or more distribution layers, wherein at least one distribution layer comprises a siloxane epoxy polymer selected from the group consisting of polymers comprising the following repeating units of formulae (X) and (XII): 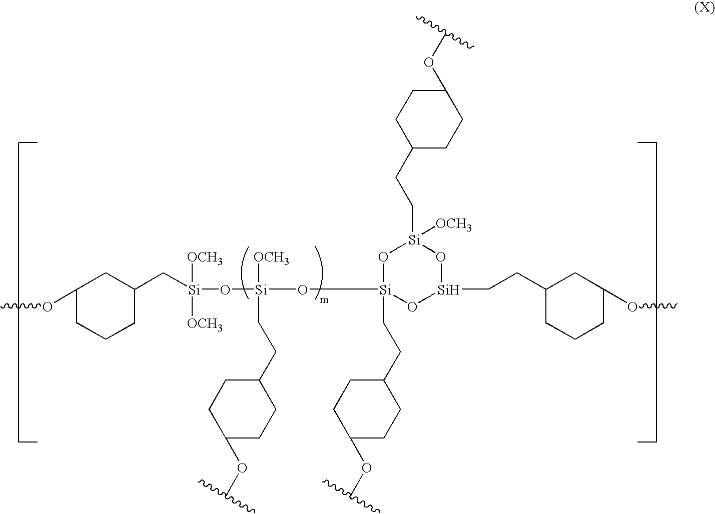
wherein m is an integer ranging from 5 to 50; and 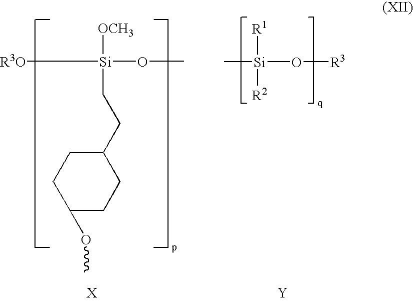
wherein X and Y are units randomly distributed or occurring together; R¹ and R² are each independently selected from the group of methyl, methoxy, ethyl, ethoxy, propyl, butyl, pentyl, octyl, and phenyl; R³ is methyl or ethyl; p is an integer ranging from 2 to 50; and q is 0 or an integer ranging from 1 to 50.

34. The device of claim 33, wherein said at least one distribution layer comprises a pattern thereon measuring between 1.0 nm and 10 μm.
